(19) United States
(12) Patent Application Publication
(10) Pub. No.: US 2025/0299961 A1
(43) Pub. Date: Sep. 25, 2025

(54) SELECTIVE DEPOSITION OF COBALT AND RUTHENIUM, AND RELATED STRUCTURES

(71) Applicant: ENTEGRIS, INC., Billerica, MA (US)

(72) Inventors: Jun-Fei Zheng, Westport, CT (US); Paul Besser, Sunnyvale, CA (US); Phil S.H. Chen, Bethel, CT (US)

(21) Appl. No.: 19/071,864

(22) Filed: Mar. 6, 2025

Related U.S. Application Data
(60) Provisional application No. 63/567,608, filed on Mar. 20, 2024.

(51) Int. Cl. H01L 21/285; H10D 64/64

(52) U.S. Cl. CPC H01L 21/28518; H10D 64/647

(57) ABSTRACT

Described are methods of selectively depositing a cobalt or ruthenium seed layer onto a semiconductor substrate, methods of forming a conductive contact on the semiconductor substrate, and semiconductor substrates formed according to the methods.

### CROSS-REFERENCE TO RELATED APPLICATION

This application claims priority to and the benefit of U.S. Provisional Application No. 63/567,608, filed on Mar. 20, 2024 and which is incorporated by reference herein in its entirety for all purposes.

### FIELD

The following description relates to methods of selectively depositing cobalt or ruthenium onto a semiconductor substrate, methods of forming a bulk metal structure (e.g., conductive contact) on a semiconductor substrate, and semiconductor substrates formed according to the methods.

### BACKGROUND

For current technology nodes (e.g., N2 node and beyond), backside contact for power distribution network (BSPDN) integration incorporates direct metal contact to source and drain areas of a GAA (gate all around) transistor from the backside. The size of the contact via is small and exhibits a high aspect ratio. A low resistance bulk metal contact structure is desired.

By current methods, a source or drain contact is formed in a contact hole of a dielectric layer by first depositing a titanium nitride barrier or “liner” to conformally cover the dielectric sidewall and a silicide bottom layer of the contact hole or “via.” The via then is filled by conventional chemical vapor deposition, for example of tungsten, in a conformal (non-selective) manner. The titanium nitride liner is undesirable as part of the contact structure because titanium nitride is a high resistive metal. In addition, conventional chemical vapor deposition to form the bulk tungsten contact involves conformal deposition, which may produce a seam or void at the contact interior that increases resistivity of the contact. The presence of the titanium nitride liner on the dielectric sidewall does not allow selective tungsten growth in a “bottom-up” fill step from the bottom of the contact hole opening that would prevent the formation of the seam. A need remains for methods that allow a bottom-up fill step of the conductive contact.

### SUMMARY

For backside power distribution networks in N2 nodes, a need exists to form a metal contact (e.g., tungsten or another conductive contact metal) directly onto a source or drain region of a semiconductor layer through a via having a dimension of tens of nanometers, by a bottom-up fill step and without the need for a liner coated onto dielectric via sidewalls.

A bottom-up fill step requires a conductive “nucleation layer” or “seed layer” that is selectively deposited at a surface of a doped semiconductor region located at a bottom (“bottom surface”) of a contact hole (“opening” or “via”). As described herein, a conductive nucleation layer is deposited with high selectivity on the surface of the doped semiconductor region relative to the surrounding dielectric sidewall surfaces. A low resistance source or drain contact material (“conductive contact”) can then be selectively deposited to fill the contact hole by a bottom-up method to produce a liner-less and seam-free conductive contact within the via.

The selective bottom-up via fill process requires selective deposition of a conductive nucleation layer at the bottom surface of the contact hole, i.e., without deposition (nucleation) of the conductive nucleation layer on the dielectric sidewalls surface. Methods as described involve selectively depositing a thin layer of cobalt or ruthenium as a “seed layer” or “nucleation layer” onto the bottom surface of the via. The cobalt or ruthenium layer will not deposit onto the dielectric sidewalls of the via and serves as a nucleation layer only on the bottom surface of the via to enable selective, bottom-up deposition of the contact metal to fill the via.

In one aspect, the description relates to a method of selectively depositing conductive seed layer onto a microelectronic device substrate. The substrate includes: a semiconductor layer comprising a doped semiconductor region having a doped semiconductor region surface comprising a doped semiconductor or a silicide; and a dielectric layer disposed on the semiconductor layer, the dielectric layer comprising the opening feature above the doped semiconductor region surface, the opening feature comprising a dielectric sidewall surface. The method includes selectively depositing conductive seed layer onto the doped semiconductor region surface, the conductive seed layer comprising cobalt or ruthenium.

In another aspect, the description relates to a semiconductor substrate that includes: a semiconductor layer comprising a doped semiconductor region comprising a doped semiconductor region surface; a dielectric layer disposed on the semiconductor layer, the dielectric layer comprising a three-dimensional opening feature above the doped semiconductor region, the opening feature comprising a bottom opening located above the doped semiconductor region, an upper opening, and dielectric sidewalls extending between the bottom opening and the upper opening; and a conductive seed layer at the doped semiconductor region surface, the conductive seed layer comprising cobalt or ruthenium.

### BRIEF DESCRIPTION OF THE FIGURES

To assist in understanding the present disclosure, reference is now made to the following description taken in conjunction with the accompanying drawings, in which:

FIG. 1 shows a previous method of forming a tungsten drain or source contact by a conformal, non-selective deposition of tungsten.

FIG. 2 shows a method that uses a selective bottom-up fill step to form a tungsten drain or source contact.

FIG. 3 shows a method that uses a selective bottom-up fill step to form a tungsten drain or source contact.

FIG. 4 shows a method that uses a selective bottom-up fill step to form a drain or source contact that comprises cobalt or ruthenium.

FIG. 5 shows an inventive method that uses a selective bottom-up fill step to form a drain or source contact that comprises cobalt or ruthenium.

While the disclosure is amenable to various modifications and alternative forms, specifics thereof have been shown by way of example in the drawings and will be described in detail below. It is to be understood, however, that the intention is not to limit the disclosure to the embodiment(s) described. On the contrary, the disclosure is intended to cover all modifications, equivalents, and alternatives falling within the scope of the disclosure as defined by the appended claims.

### DETAILED DESCRIPTION

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Accordingly, in any one or more of the embodiments disclosed herein, a particular structural component being disposed between two other structural elements can be: disposed directly between both of the two other structural elements such that the particular structural component is in direct contact with both of the two other structural elements; disposed directly next to only one of the two other structural elements such that the particular structural component is in direct contact with only one of the two other structural elements; disposed indirectly next to only one of the two other structural elements such that the particular structural component is not in direct contact with only one of the two other structural elements, and there is another element which is disposed between the particular structural component and the one of the two other structural elements; disposed indirectly between both of the two other structural elements such that the particular structural component is not in direct contact with both of the two other structural elements, and other features can be disposed therebetween; or any combination(s) thereof

The present description relates to semiconductor substrates that include backside contacts for power distribution with direct metal contact to source and drain areas, and methods of forming these contacts (“conductive contacts”). According to example methods, a cobalt or ruthenium seed layer is selectively deposited onto a surface of a doped semiconductor region at a bottom surface of a contact hole, while not depositing the seed layer on the dielectric sidewall; the seed layer deposited onto the surface of the doped semiconductor region allows the use of a selective bottom-up fill method to form the conductive contact within the contact hole, to produce a low resistance conductive contact for backside contact in BSPDN integration.

Transistor source and drain contacts (“conductive contacts”) are formed as bulk metal structures within in a three-dimensional opening feature (“contact hole” or “via”) of a dielectric layer of a microelectronic device substrate. The substrate includes a semiconductor layer having a doped semiconductor region, and the dielectric layer adjacent to the semiconductor layer. The dielectric layer may be a layer of electrically-resistive silicon-containing material such as SiO₂, SiN, doped polysilicon, undoped polysilicon, among others. The dielectric layer includes a three-dimensional opening feature (a.k.a., a “contact hole” or “via”) that is located above the doped semiconductor region of the semiconductor layer. Contact metal is deposited onto the substrate to fill the contact hole to form the conductive contact (e.g., a source or drain contact).

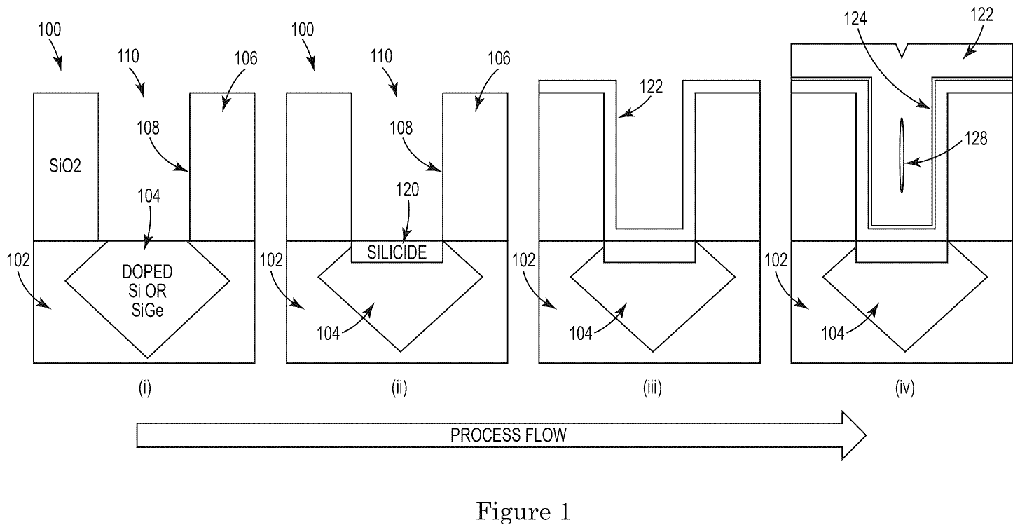

By a conventional technique, known as a “tungsten plug process,” pure tungsten is deposited onto the substrate to fill the contact hole and form the conductive contact. Tungsten is often used because of the extraordinarily good conformality achieved using tungsten hexafluoride (WF₆) as a chemical precursor of a chemical vapor deposition technique. The processes requires the use of an adhesion or barrier layer (“liner”) that is first deposited onto surfaces of the contact hole to become located between the tungsten and the dielectric layer, and between the tungsten and the semiconductor layer (see FIG. 1). The liner may be made of titanium or titanium nitride (TiN) and functions to protect the dielectric surface from attack by fluorine and to improve adhesion of the tungsten to the dielectric surface.

An example of this method is shown at FIG. 1. The method begins with a semiconductor substrate 100 that includes a semiconductor layer (102), a doped semiconductor region (104) as part of the semiconductor layer, a dielectric layer (106) (e.g., SiO₂) disposed on the semiconductor layer (102), and a three-dimensional opening feature (110) (“contact hole” or “opening” or “via”) formed in the dielectric layer. The three-dimensional opening feature 110 is located above the doped semiconductor region (104) and includes dielectric sidewalls 108.

Initially, at (i), contact hole 110 is empty and the surfaces of sidewalls 108 are exposed surfaces of the dielectric material of dielectric layer 106. Contact hole 110 is available to deposit a contact metal into the contact hole to form a conductive contact of bulk deposited contact metal. According to a “silicide formation” step, (ii), a silicide layer 120 is formed at the surface of doped semiconductor region 104, i.e., at the bottom surface of opening 110. Subsequently, (iii), a liner (e.g., titanium (Ti) and/or titanium nitride (TiN)) 122 is conformally deposited to cover silicide layer 120 and to cover the dielectric surface of sidewalls 108. The titanium and titanium nitride layer 122 is formed using a conformal, non-selective deposition technique, and consequently covers both silicide layer 120 and dielectric sidewalls 108. In some examples, the silicide layer (120) is formed after the liner layer is deposited.

At step (iv), a tungsten seed layer (124) is conformally deposited over titanium nitride layer 122. By a subsequent non-selective “fill step,” a conductive contact 126 (e.g., bulk tungsten) is formed within the remaining interior space of contact hole 110 using a conformal chemical vapor deposition technique. As illustrated, because tungsten contact 126 is formed using a conformal (non-selective) deposition technique, tungsten contact 126 includes a central gap or “seam” 128, which undesirably reduces the conductivity of tungsten contact 126. Also undesirably, liner (e.g., titanium nitride layer) 122 has a thickness that consumes space within contact hole 110 and reduces the size of tungsten contact 126 and further reduces the conductivity of tungsten contact 126.

In a subsequent step (not shown) the layers of material that were deposited onto the upper surface of dielectric layer 106 and above contact hole 108, e.g., liner material 122 and tungsten seed layer 124, are removed by a chemical mechanical planarization (a.k.a. chemical mechanical polishing or chemical mechanical polishing) (CMP) step before further processing.

A novel method as described herein can be performed to avoid unwanted effects of the above-described steps for forming a conductive contact using a conformal (non-selective) fill step as shown at FIG. 1. The present methods advantageously allow for a “bottom-up” conductive contact fill step by first selectively depositing a “conductive seed layer” as a nucleating layer at the bottom of opening 110, e.g., at the surface of doped semiconductor region 104.

The conductive seed layer of cobalt or ruthenium can be selectively deposited onto a surface of the doped semiconductor region, which may be, e.g., a doped semiconductor region surface, or a silicide surface formed on the doped semiconductor region surface. The conductive seed layer allows for a step of selectively depositing a contact metal onto the substrate to fill opening 110 and form the conductive contact by a bottom-up fill step.

The conductive seed layer is cobalt or ruthenium, which can be selectively deposited onto the surface of the doped semiconductor region. With the conductive seed layer at the bottom of the contact hole, a subsequent step can be performed to selectively deposit contact metal only on the conductive seed layer without the contact metal becoming deposited on the dielectric sidewall surfaces; the deposited contact metal thereby accumulates and builds a thickness within (fills) the contact hole in a “bottom-up” fashion, not accumulating on or building a thickness from the side surfaces.

The semiconductor layer can be a semiconductor material such as silicon, germanium, or silicon germanium, with doped regions such as doped silicon, doped germanium, or doped silicon germanium. The doped regions may be “heavily-doped,” meaning silicon, germanium, or silicon germanium that contains at least 1×10²⁰ at/cm³ dopant.

The conductive seed layer may be made of cobalt or ruthenium, preferably having a high purity.

The conductive seed layer is selectively deposited onto the surface of the doped semiconductor region of the semiconductor layer. In different versions of the described methods, the surface of the doped semiconductor region may be the surface of the doped semiconductor region (e.g., doped silicon, doped germanium, or doped silicon germanium), or may be a surface of a silicide layer that is formed on the doped semiconductor region. According to examples of the former, the conductive seed layer may be selectively deposited directly onto the surface of the doped semiconductor region, e.g., a heavily doped semiconductor region. According to examples of the latter, the surface of the doped semiconductor region may be chemically processed to form a silicide (e.g., WSi₂, TaSi₂, CrSi₂, MoSi₂), and the conductive seed layer may be selectively deposited onto the surface of the silicide.

The contact metal that is selectively deposited onto the conductive seed layer may be any metal (including alloys) that is useful as a conductive contact and is capable of selective deposition as described, such as tungsten, cobalt, ruthenium, copper, rhodium, palladium, nickel, iridium, or a combination of these.

According to example methods, a conductive seed layer of ruthenium or cobalt is first selectively deposited onto a surface of the doped semiconductor region, which may be either the surface of the doped semiconductor region or a surface of a silicate formed on the doped semiconductor region. After forming the conductive seed layer, additional contact metal is deposited into the opening to continuously accumulate within the opening in a “bottom-up” fashion, without becoming deposited onto the dielectric sidewalls; i.e., the bottom-up deposition technique is selective in depositing the conductive material at the bottom surface of the opening relative to the dielectric sidewalls.

Advantageously, the bottom-up deposition technique avoids the need for an adhesion or barrier layer (“liner”) that covers the dielectric sidewall surfaces of the three-dimensional opening feature or the bottom surface of the opening feature. The resulting bulk metal conductive structure (e.g., conductive contact) that becomes deposited into the three-dimensional opening completely fills the opening. The need for an adhesion or barrier layer is eliminated, and more space remains within the opening for the contact metal, advantageously increasing the conductivity of the conductive contact. Moreover, the bottom-up deposition technique does not cause a gap or “seam” to form within the conductive contact that would reduce the conductivity of the conductive contact.

While the methods do not require and can specifically exclude the need for a liner or adhesion or barrier layer conformally deposited onto the dielectric sidewall, the described methods allow for treating the dielectric sidewall in a manner that does not form such a layer of added material. For example, the dielectric sidewall surface may be modified at an atomic level to enhance the ability to perform a bottom-up fill step of the conductive contact, i.e., to avoid conformal deposition of the conductive contact. A step of modifying a dielectric surface in this manner does not add a layer or a coating of a liner material onto the dielectric surface and does not significantly reduce the volume of the contact hole before a step of filling the contact hole with a contact metal.

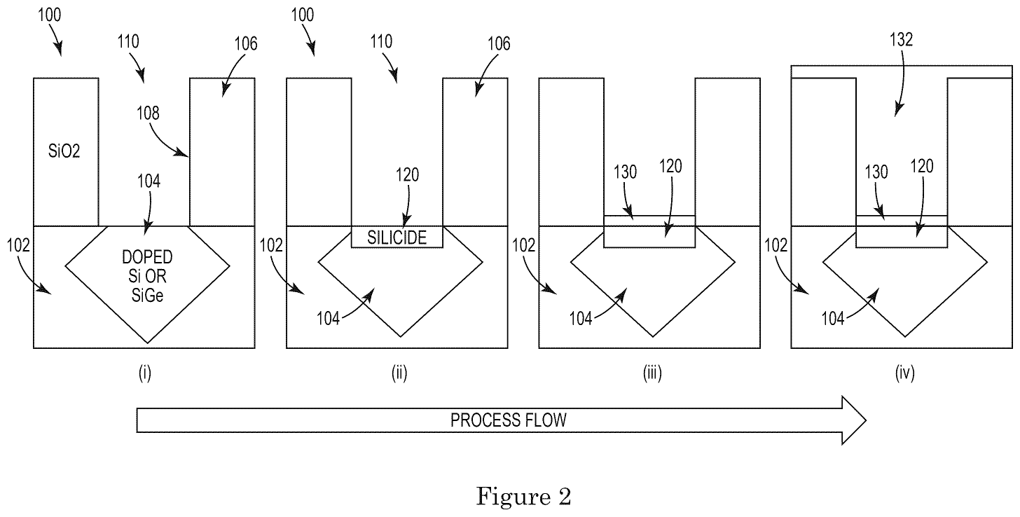

An example method is shown at FIG. 2. The method begins with a semiconductor substrate 100 that contains a semiconductor layer (102), a doped semiconductor region (104) as part of the semiconductor layer, a dielectric layer (106), and a three-dimensional opening feature (110) formed in the dielectric layer. The three-dimensional opening feature 110 is located above doped semiconductor region 104 and includes dielectric sidewalls 108.

Initially, at (i), contact hole 110 is empty and the surfaces of sidewalls 108 are formed of exposed dielectric material of dielectric layer 106. In “silicide formation” step, (ii), a silicide layer 120 is formed at the surface of doped semiconductor region 104. Subsequently, (iii), conductive seed layer 130 made of seed layer metal 130 that includes cobalt or ruthenium is selectively deposited onto the surface of silicide layer, meaning that seed layer 130 deposits onto the surface of silicide 120 without becoming deposited onto surfaces of sidewalls 108.

At step (iv), a contact metal (e.g., tungsten) fill step, a conductive tungsten contact 132 is formed, e.g., by chemical vapor deposition of tungsten. Tungsten contact 132 is formed by a selective, non-conformal, bottom-up method of depositing a conductive metal (e.g., tungsten) to fill contact hole 110 and, therefore, does not includes a central gap or “seam” that would undesirably reduce the conductivity of tungsten contact 132. Also, tungsten contact 132 advantageously fills the entire space of contact hole 110 without an adhesion or barrier layer or “liner” included between sidewalls 108 of dielectric layer 106 and tungsten contact 132 that would reduce the size and conductivity of tungsten contact 132.

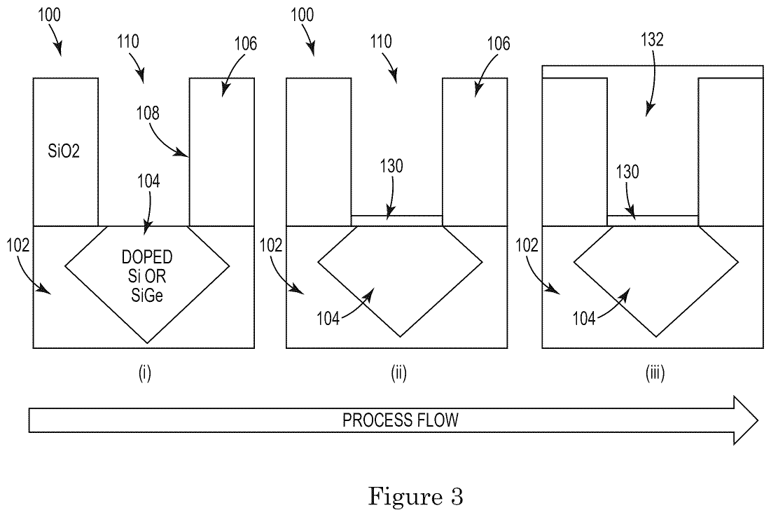

In an alternate example illustrated at FIG. 3, conductive contact 130 may be deposited directly onto the surface of doped semiconductor region 104, without the need to first form a silicide on the surface of doped semiconductor region 104. As illustrated, at (i), contact hole 110 is initially empty and the surface of doped semiconductor region 104 is exposed at the bottom of contact hole 110. In step (ii), conductive seed layer 130 of cobalt or ruthenium is selectively deposited onto the surface of doped semiconductor region 104; meaning that seed layer 130 is deposited directly onto the surface of doped semiconductor region 104 and does not become deposited onto surfaces of sidewalls 108. At step (iii), conductive contact 132 is formed by a bottom-up deposition technique. Conductive contact 132 (for example tungsten), formed by a bottom-up technique, does not include a central gap or “seam” that would undesirably reduce the conductivity of conductive contact 132. Conductive contact 132 fills the entire space of opening 110 with no adhesion or barrier layer or “liner” present between sidewalls 108 of dielectric layer 106.

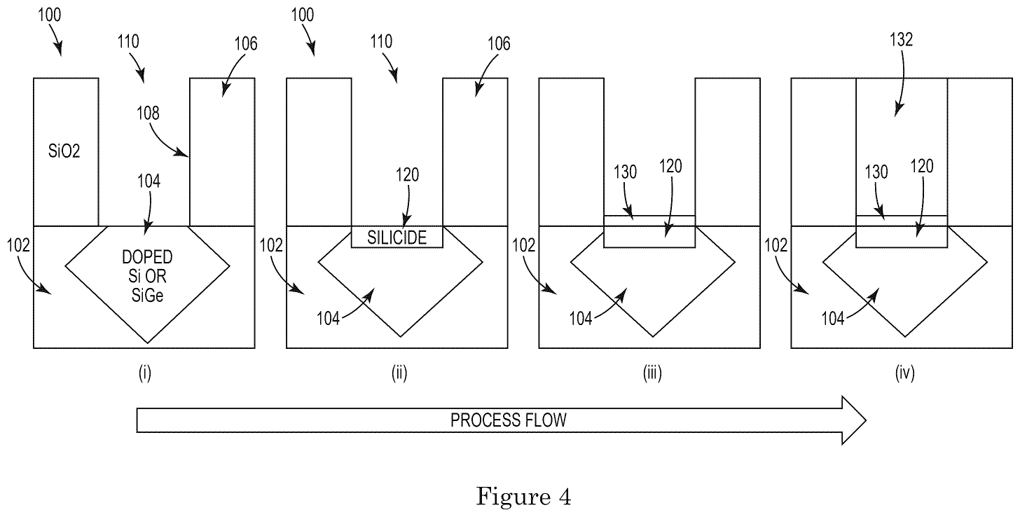

Methods as described can be used to form the conductive contact from tungsten as shown at FIGS. 2 and 3 and may also be used to form a conductive contact from another contact metal e.g., contact metal that comprises ruthenium, cobalt, copper, or the like, or a combination of any of these. An example method is at FIG. 4, showing shows steps (i), (ii), and (iii) that are similar to those of FIG. 2. Different from step (iv) of FIG. 2, at step (iv) of FIG. 4, conductive contact 132 is formed of a contact metal that is different from tungsten, such as cobalt, ruthenium, or a combination of these, e.g., by a bottom-up chemical vapor deposition step.

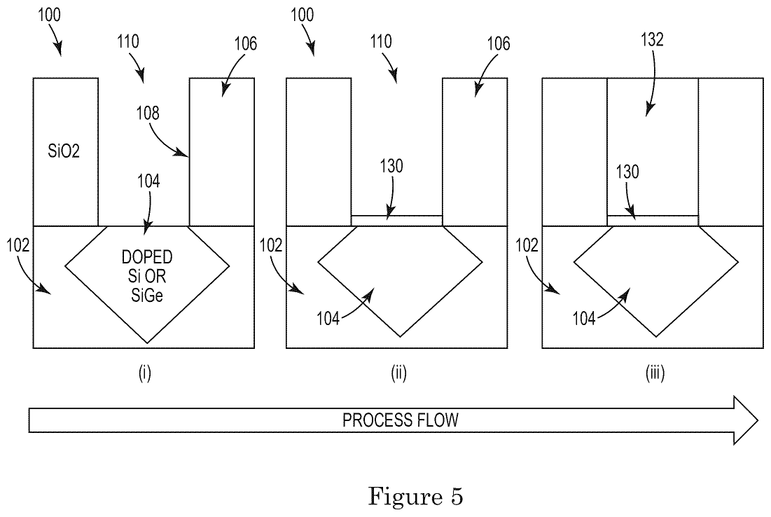

FIG. 5 shows another example method by which, in step (ii), conductive seed layer 130 of cobalt or ruthenium is selectively deposited directly onto the surface of the doped semiconductor region 104, meaning that conductive seed layer 130 is selectively deposited directly onto the surface of doped semiconductor region 104 and does not become deposited onto surfaces of sidewalls 108. At step (iii), conductive contact 132 is formed of a contact metal such as cobalt, ruthenium, or a combination of these by bottom-up deposition step.

According to example methods that use cobalt or ruthenium as a conductive seed layer, and subsequently form the conductive contact from cobalt or ruthenium, the method may advantageously use the same metal for both the conductive seed layer and the contact metal used to form the conductive contact. For example, as illustrated at FIGS. 4 and 5, conductive seed layer 130 and conductive contact 132 may both be made of cobalt, or may both be made of ruthenium. Using the same metal, either cobalt or ruthenium, for both the conductive seed layer and the conductive contact allows both of these structures to be deposited from a single chemical precursor and during a single deposition step.

An additional advantage of forming the conductive contact from cobalt or ruthenium as opposed to tungsten is that these contact metals eliminate a step of chemical mechanical planarization that would be needed when depositing tungsten as a contact metal to form a tungsten contact. The conventional process using tungsten deposits the tungsten in the field region as well as in the contact/via region, necessitating a CMP process.

The described methods involve depositing cobalt or ruthenium as a conductive seed layer onto a surface of a doped semiconductor region, e.g., directly onto the doped semiconductor region surface or onto a silicide formed on the doped semiconductor region. The method of depositing the conductive seed layer is selective, meaning that the conductive seed layer becomes deposited onto the bottom surface without being deposited onto the dielectric sidewall surfaces of the contact hole.

A step of selectively depositing ruthenium or cobalt onto a surface of a doped semiconductor region may be performed by any useful deposition technique, such as atomic layer deposition (e.g., PEALD (plasma-enhanced atomic layer deposition), chemical vapor deposition (e.g., plasma-enhanced chemical vapor deposition), etc.

Methods and precursors for selectively depositing ruthenium or cobalt onto a substrate as described in United Staes patent publications 2020/0157680, 2022/0267895 and 2023/0245894, the entireties of which are incorporated herein by reference. Examples of precursors for use in selectively depositing cobalt or ruthenium include p-cymene-1,3-cyclohexandiene ruthenium (CAS No. 500591-28-6), and bis(N,N′-di-tert-butyl-1,4-diaza-1,3 butadienyl) cobalt (CAS No 177099-51-3) (C₂₀H₄₂CoN₄).

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

1. A method of selectively depositing a conductive seed layer onto a microelectronic device substrate, the substrate comprising:
a semiconductor layer comprising a doped semiconductor region having a doped semiconductor region surface comprising a doped semiconductor or a silicide,
a dielectric layer disposed on the semiconductor layer, the dielectric layer comprising the opening feature above the doped semiconductor region surface, the opening feature comprising a dielectric sidewall surface,
the method comprising:
selectively depositing a conductive seed layer onto the doped semiconductor region surface, the conductive seed layer comprising cobalt or ruthenium.

2. The method of claim 1, wherein the conductive seed layer selectively deposits onto the doped semiconductor region surface without being deposited onto the dielectric sidewall surface.

3. The method of claim 1, wherein the doped semiconductor region comprises doped silicon, doped germanium, or doped silicon germanium.

4. The method of claim 1, comprising selectively depositing contact metal onto the conductive seed layer to form a conductive contact within the opening by bottom-up growth of the conductive contact.

5. The method of claim 1, wherein the doped semiconductor region surface comprises heavily-doped silicon, heavily-doped germanium, or heavily-doped silicon germanium, and the method comprises selectively depositing the conductive seed layer directly onto the doped heavily-doped silicon, heavily-doped germanium, or heavily-doped silicon germanium.

6. The method of claim 5, wherein the heavily-doped silicon, heavily-doped germanium, or heavily-doped silicon germanium contains at least 1×10²⁰ at/cm³ dopant.

7. The method of any of claim 1, wherein the doped semiconductor region surface comprises a silicide surface formed on the doped semiconductor region, the method comprising:
forming the silicide surface on the doped semiconductor region, and
selectively depositing the conductive seed layer on the silicide surface.

8. The method of claim 1, wherein the dielectric sidewall surface comprises dielectric silicon material.

9. The method of claim 4, wherein the conductive contact directly contacts the dielectric sidewall surface.

10. The method of claim 4, wherein the conductive contact is tungsten and does not include a seam formed by conformal deposition of the tungsten.

11. A semiconductor substrate comprising:
a semiconductor layer comprising a doped semiconductor region comprising a doped semiconductor region surface,
a dielectric layer disposed on the semiconductor layer, the dielectric layer comprising a three-dimensional opening feature above the doped semiconductor region, the opening feature comprising a bottom opening located above the doped semiconductor region, an upper opening, and dielectric sidewalls extending between the bottom opening and the upper opening, and
a conductive seed layer at the doped semiconductor region surface, the conductive seed layer comprising cobalt or ruthenium.

12. The semiconductor substrate of claim 11, comprising a conductive contact that fills the opening feature between the conductive seed layer and the upper opening, and that contacts the dielectric sidewalls.

13. The semiconductor substrate of claim 11, wherein the doped semiconductor region surface comprises heavily-doped silicon, heavily-doped germanium, or heavily doped silicon germanium and the conductive seed layer contacts the heavily-doped silicon, heavily-doped germanium, or heavily doped silicon germanium.

14. The semiconductor substrate of claim 11, wherein the doped semiconductor region surface comprises a silicide.

15. The semiconductor substrate of claim 11, wherein the conductive contact directly contacts the dielectric sidewall surface.

16. The semiconductor substrate of claim 11, wherein the conductive contact is a source contact or a drain contact.

17. The semiconductor substrate of claim 11, wherein the conductive contact comprises metal selected from tungsten, cobalt, ruthenium, copper, rhodium, palladium, nickel, and iridium.

18. The semiconductor substrate of claim 11, wherein the conductive contact is tungsten, and the conductive contact does not include a seam formed by conformal deposition of the tungsten.
